(19) United States
(12) Patent Application Publication
(10) Pub. No.: US 2017/0012179 A1
(43) Pub. Date: Jan. 12, 2017

(54) LIGHT-EMITTING DEVICE AND METHOD OF PRODUCING A LIGHT-EMITTING DEVICE

(71) Applicant: OSRAM OPTO SEMICONDUCTORS GMBH, Regensburg (DE)

(72) Inventors: Norwin von Malm, Nittendorf (DE); Britta Göötz, Regensburg (DE)

(21) Appl. No.: 15/113,198

(22) PCT Filed: Jan. 20, 2015
(86) PCT No.: PCT/EP2015/050999

§ 371 Date: Jul. 21, 2016

(30) Foreign Application Priority Data
Jan. 24, 2014 (DE) 10 2014 100 837.5

(51) Int. Cl. H01L 33/50; H01L 51/00; C08G 61/02; H01L 51/52

(52) U.S. Cl. CPC H01L 33/502; H01L 51/5262; H01L 51/0001; H01L 51/0035; C08G 61/02; H01L 51/0055; H01L 51/0053; H01L 2933/0041; H01L 2933/0033; C08G 2261/3424

(57) ABSTRACT

A light-emitting device includes a conversion element including a light-emitting surface provided with a conversion layer, wherein the conversion layer contains a matrix material and a converter material, both the matrix material and the converter material are materials that can be vaporized under high vacuum, the matrix material and the converter material are applied to the light-emitting surface by vaporization under a high vacuum, and the matrix material has the structural formula

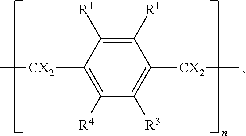

where R¹, R², R³, R⁴ and X may be mutually independently selected from the group comprising F, Cl and H, and n>=2.

### TECHNICAL FIELD

This disclosure relates to a light-emitting device and a method of producing such a light-emitting device.

### BACKGROUND

It could be helpful to provide a light-emitting device with a conversion element that is particularly stable as well as a method of producing such a light-emitting device.

### SUMMARY

We provide a light-emitting device including a conversion element including a light-emitting surface provided with a conversion layer, wherein the conversion layer contains a matrix material and a converter material, both the matrix material and the converter material are materials that can be vaporized under high vacuum, the matrix material and the converter material are applied to the light-emitting surface by vaporization under a high vacuum, and the matrix material has the structural formula

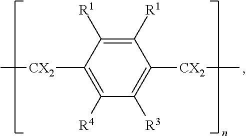

wherein R¹, R², R³, R⁴ and X may be mutually independently selected from the group comprising F, Cl and H, and n≧2.

We also provide a method of producing a light-emitting device including A) providing a surface provided for radiation emission, and B) vapor depositing a conversion layer under high vacuum onto the surface provided for radiation emission, wherein the conversion layer includes a matrix material and a converter material simultaneously applied to the surface provided for radiation emission, and the matrix material has structural formula

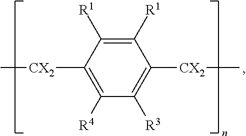

wherein R¹, R², R³, R⁴ and X may be mutually independently selected from the group comprising F, Cl and H, and n≧2.

### BRIEF DESCRIPTION OF THE DRAWINGS

FIG. 1 is a schematic side view of a light-emitting device with reference to an example of an organic light-emitting diode.

FIG. 2 is a schematic side view of an example of an organic light-emitting diode.

FIGS. 3a, 3b, 4a, 4b, 5, 6a, 6b, 6c and 7 are each schematic side views of an example of a light-emitting device in the form of a light-emitting diode.

### DETAILED DESCRIPTION

Our light-emitting device may comprise a conversion element. The conversion element may comprise a light-emitting surface. The light-emitting surface is provided with a conversion layer. “Provided with a conversion layer” means direct or indirect contact between the light-emitting surface of the conversion element and the conversion layer.

The conversion layer may be arranged on an electrode layer of a light-emitting device, for example, an organic light-emitting diode. The electrode layer may take the form of an anode. The anode is in particular semi-transparent. The electrode layer may comprise indium-tin oxide (ITO) and/or a metal such as silver, aluminum, cadmium, barium, indium, magnesium, calcium, lithium or gold or consist of one or more of the stated metals. In particular, the conversion layer is arranged on a semi-transparent anode and the light-emitting device is formed as a top-emitter. Alternatively, the electrode layer may be formed as a cathode.

The conversion layer may be arranged on a substrate or carrier. The substrate or the carrier may, for example, be glass.

The conversion layer may be directly arranged on a semiconductor element of a light-emitting device or at least arranged downstream thereof in the beam path. “At least arranged downstream thereof” means that further layers, for example, a bonding layer are present between the conversion layer and the semiconductor element. The semiconductor element is in particular arranged in a light-emitting diode (LED).

The semiconductor element is preferably based on a III-V compound semiconductor material. The semiconductor material is preferably a nitride compound semiconductor material such as AlₙIn₁₋ₙ₋ₘGaₘN or indeed a phosphide compound semiconductor material such as AlₙIn₁₋ₙ₋ₘGaₘP, wherein in each case 0≦n≦1, 0≦m≦1 and n+m≦1. Likewise, the semiconductor material may be AlₓGa₁₋ₓAs, with 0≦x≦1. The semiconductor layer sequence may comprise dopants and additional constituents. For simplicity's sake, however, only the essential constituents of the crystal lattice of the semiconductor layer sequence are indicated, i.e., Al, As, Ga, In, N or P, even if these may in part be replaced and/or supplemented by small quantities of further substances.

The semiconductor element may contain an active layer with at least one pn junction and/or with one or with a plurality of quantum well structures. When the semiconductor element is in operation, electromagnetic primary radiation is generated in the active layer. A wavelength of the primary electromagnetic radiation is preferably in the ultraviolet and/or visible region of the spectrum, in particular at wavelengths of 420 nm to 680 nm, for example, 440 nm to 480 nm.

The conversion layer may comprise a conversion material and a transparent matrix material surrounding the conversion material. The matrix material may be applied under a high vacuum to the light-emitting surface. The matrix material may have the structural formula

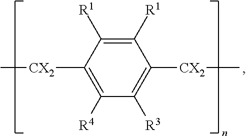

wherein R¹, R², R³, R⁴ and X may be mutually independently selected. R¹, R², R³, R⁴ and X may be selected from a group comprising alkyl, aryl, heteroaryl, ether groups, ethoxy groups, hydrogen, carbon, nitrogen, sulfur and halogens such as fluorine, chlorine, bromine or iodine.

In particular, R¹, R², R³, R⁴ and X are mutually independently selected and/or selected from the group comprising F, Cl and H.

The following applies: n≧2, wherein n signifies the number of monomer units of the matrix material. In particular, n is greater than or equal to 1000 and less than or equal to 5000, preferably between 1500 and 4000, for example, 2000.

R¹, R², R³, R⁴ and X may in each case be hydrogen. Alternatively, R² may be chlorine and R², R³, R⁴ and X in each case hydrogen. Alternatively, R¹ and R³ may in each case be chlorine and R² and R⁴ and X in each case hydrogen. Alternatively, R¹, R², R³ and R⁴ may in each case be hydrogen and X fluorine.

The matrix material may be a poly(p-xylylene). Poly(p-xylylene)s may also be called parylenes or PPX. Parylenes are a group of inert, hydrophobic, optically transparent, polymeric coating materials. PPX may be produced by chemical vapor deposition polymerization (CVDP) of paracyclophane, p-xylene or esters or ethers of α,α-bis(hydroxymethyl)-p-xylene. The advantage of the CVDP method is that PPX can be produced with high chemical purity, i.e., without the PPX being contaminated with solvent molecules. Furthermore, insoluble polymers may be produced in various shapes and nano-dimensions using CVDP methods.

Options A) to E) for producing the matrix material using gas deposition with R, R², R³, R⁴ and X in each case being H are shown below:

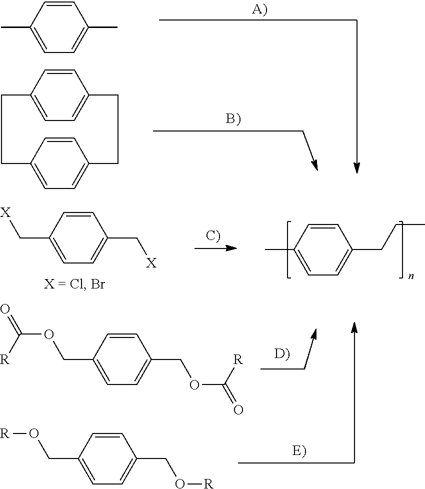

Options A) to E) for producing the matrix material are however also in principle suitable for starting materials with residues R¹, R², R³, R⁴ and X other than those stated above.

Option A) for producing the matrix material by chemical gas deposition will be described below: the starting material may be p-xylene (1) or halogenated derivatives thereof. This p-xylene vaporizes and is passed through a high temperature zone at around 250° C. In the process, a reactive [2,2]-paracyclophane (2) forms, which decays to yield 1,4-quinonedimethane (3). The quinonedimethane (3) polymerizes on surfaces, in particular a surface of the conversion element, immediately to yield chain-form poly-p-xylene (4) with R¹, R², R³, R⁴ and X in each case being H.

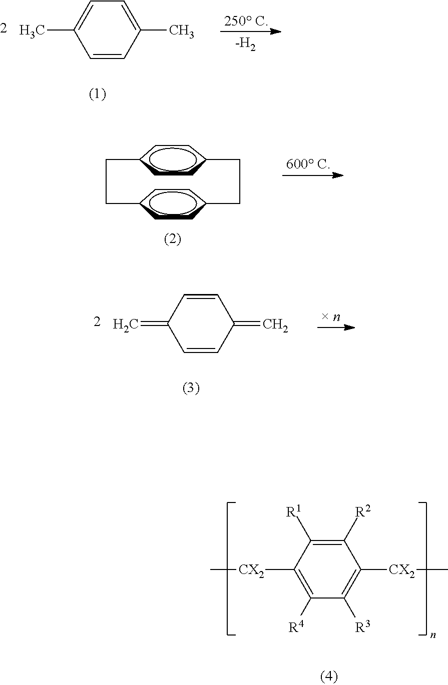

The use of PPX as a matrix material has the advantage that the PPX is chemically inert. In particular, the matrix material is chemically resistant when exposed to radiation from the blue spectral region. Furthermore, the matrix material exhibits transparency to wavelengths in the blue region of the spectrum. The blue region of the spectrum means in particular at least a wavelength maximum of 460 nm to 480 nm. The matrix material is chemically resistant and may be used as a moisture barrier for moisture-sensitive conversion materials. In other words, the matrix material may envelop a conversion material in particle or individual molecule form. The matrix material may thus function as a barrier against moisture and/or oxygen and/or acidic gases. The matrix material may additionally also exhibit a good barrier action against inorganic and organic media, strong acids, alkalies, gases and water vapor. This increases the stability of the converter material. Thanks to the barrier action of the PPX as a matrix material, the converter material may consist of chemically reactive substances, in particular organic molecules sensitive to oxygen and/or moisture. At the same time, thanks to the barrier action of the PPX as a matrix material, the light-emitting device is also protected against environmental influences. Furthermore, deposition from the gas phase enables simple and uniform intermixing of matrix material and converter material.

The matrix material may additionally take the form of a thin layer, for example, with a film thickness of less than or equal to 10 nm. In particular, the thin layer is additionally transparent. This is advantageous since such a thin layer has good gap penetration and thus, on deposition, displays very good edge coverage over an electrode layer or a semiconductor element of the light-emitting device.

Furthermore, the matrix material may be corrosion-resistant, thermally resistant to 220° C. and mechanically stable from −200° C. to 150° C.

The conversion layer may comprise a converter material. The converter material has a wavelength-converting action. In other words, electromagnetic radiation emitted by a radiation source may be partially or completely converted into radiation of different wavelengths. The converter material may take the form of particles or as individual molecules surrounded by the matrix material. The particles or molecules may be embedded in the matrix material, wherein the matrix material envelops the particles of the converter material and thus protects the converter material from moisture and/or acidic gases. The converter material may be an organic or inorganic material. In particular, the converter material is organic.

The converter material may comprise or consist of an organic luminescent dye.

The converter material may be selected from the following group and the combinations thereof: perylene and the derivatives thereof, diindenoperylene and the derivatives thereof, benzopyrene and the derivatives thereof, coumarin and the derivatives thereof, rhodamine and the derivatives thereof, azo compounds, terrylene and the derivatives thereof, quaterrylene and the derivatives thereof, naphthalimide and the derivatives thereof, cyanine or cyanines, phthalocyanine and the derivatives thereof, fluorescein and the derivatives thereof, fluorene and the derivatives thereof, pyrene and the derivatives thereof, pyranine and the derivatives thereof, styryls, xanthene and the derivatives thereof, oxazine and the derivatives thereof, anthracene and the derivatives thereof, naphthacene and the derivatives thereof, anthraquinone and the derivatives thereof and thiazine and the derivatives thereof.

Perylene means unsubstituted perylene. Unsubstituted perylene has the structural formula

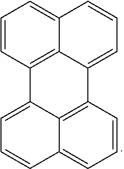 [SMILES: c1cc2cccc3c4cccc5cccc(c(c1)c23)c54]

A derivative of perylene means that the conversion material has a basic perylene structure, i.e., an unsubstituted perylene, wherein the basic perylene structure may be substituted with further substituents S1 to S12. A derivative of perylene has the following structural formula:

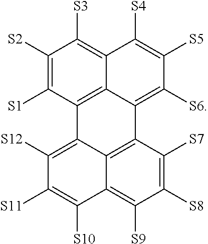

Substituents S1 to S12 may be mutually independently selected from the following group: hydrogen, alkyl, ethoxy, aryl, heteroaryl, carboxylic anhydride or diimide. In particular, substituents are preferred which protect the molecule from free-radical attack by the matrix material or the precursors thereof, for example, due to steric hindrance.

In particular, the derivative of perylene may be a 3,4,9,10-perylene tetracarboxylic acid dianhydride (PTCDA) or N,N′-dimethyl-3,4,9, 10-perylenetetracarboxylic diimide (MePTCDI).

In particular, the derivative of perylene has the following structural formula:

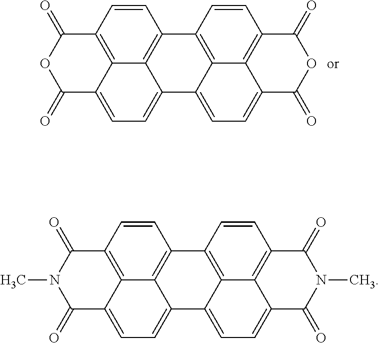 [SMILES: O=C1OC(=O)c2ccc3c4ccc5c6c(ccc(c7ccc1c2c73)c64)C(=O)OC5=O ; CN1C(=O)c2ccc3c4ccc5c6c(ccc(c7ccc(c2c37)C1=O)c64)C(=O)N(C)C5=O]

Corresponding definitions may be applied mutatis mutandis to benzopyrene and the derivatives thereof, coumarin and the derivatives thereof, terrylene and the derivatives thereof, quaterrylene and the derivatives thereof, naphthalimide and the derivatives thereof, xanthene and the derivatives thereof, oxazine and the derivatives thereof, anthracene and the derivatives thereof, naphthacene and the derivatives thereof, anthraquinone and the derivatives thereof and thiazine and the derivatives thereof.

Rhodamine means that an unsubstituted xanthene is present. “Derivative of rhodamine” means that xanthene has been derivatized.

Cyanine or cyanines denotes a chemical compound from the group of polymethine dyes.

Azo compound means that the converter material comprises at least one azo group. In particular, the azo compound is an azo dye.

Styryl means at least one fluorescent dye such as, for example, [4-[2-(4-fluorophenyl)vinyl]phenyl]diphenylamine, diphenyl-(4-styrylphenyl)amine, 3-[2-(5-tert-butylbenzooxazol-2-yl)vinyl]-9-ethyl-9H-carbazole, 1,4-bi s-[2-(4-fluorophenyl)vinyl]-2,5-bis-octyloxybenzene and/or 5-tert-butyl-2-(2-(4-(2-(5-tert-butylbenzoxazol -2-yl)vinyl)phenyl)vinyl)benzoxazole.

The converter material may be generated from a second precursor.

The second precursor may be vaporized under high vacuum and then, in particular on deposition, form the converter material. The second precursor may have a chemical composition the same as or different from that of the resultant converter material. In other words, the converter material may correspond to the second precursor, if the second precursor is not chemically modified during vaporization. Alternatively, the converter material may differ chemically from the second precursor.

The second precursor may be vaporized under high vacuum. In so doing, it is possible to produce the converter material having the same chemical composition as the second precursor.

Alternatively, the second precursor may be vaporized to form a desired variant and a converter material produced the chemical structural formula of which differs from the structural formula of the second precursor. Alternatively, it is also possible to use other second precursors chemically modified such that they may be vaporized. The second precursor may be deposited on the light-emitting surface of the conversion element, wherein the converter material forms. At the same time, a first precursor may be vaporized, from which the matrix material may be formed on deposition, as has in particular been described above. The matrix material may envelop the converter material and thus serve as an encapsulation. Alternatively, first, the converter material and then the matrix material may be deposited. A covering layer for the converter material may thus be produced from the matrix material.

The first precursor may be vaporized under high vacuum. A matrix material is formed that is chemically identical to the first precursor. Alternatively, the second precursor may be vaporized to form a desired variant. A converter material is formed, the chemical structural formula of which differs from the structural formula of the first precursor.

The matrix material or the first precursor is vaporized and decomposes to yield a monomer. Then the monomer may polymerize on separation. Polymerization of the monomers of the matrix material in particular proceeds free-radically, wherein no initiator is needed. Furthermore, catalysts do not necessarily have to be used to introduce the converter material into the matrix material. To obtain a good encapsulation result, polymerization of the matrix material is started before vaporization of the converter material. Then, vaporization of the converter material may be started, wherein, once the desired quantity of converter material has been deposited, deposition of the converter material is stopped sooner than is deposition of the matrix material. In other words, deposition of the matrix material proceeds for longer, and thus displays a lead time and an afterrun time compared with deposition of the converter material. In this way, very good encapsulation of the converter material with the matrix material may be achieved, wherein the matrix material protects the converter material from moisture and environmental influences.

The light-emitting device may comprise a conversion element, wherein the conversion element has a light-emitting surface provided with a conversion layer. The conversion layer contains a matrix material and a converter material. The matrix material and the converter material are materials vaporizable under high vacuum. The matrix material and the converter material may be applied under a high vacuum to the light-emitting surface. The matrix material has the following structural formula

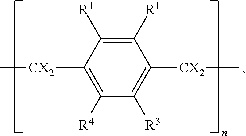

wherein R¹, R², R³, R⁴ and X may be mutually independently selected from the group comprising F, Cl and H, and

wherein n≧2.

The light-emitting device comprises a conversion element with a conversion layer and a semiconductor element. The semiconductor element comprises a light-emitting surface provided with a conversion layer. The conversion layer contains a matrix material and a converter material. The matrix material and the converter material may each be produced from a precursor, wherein the matrix material and the converter material may be produced on deposition. The precursor may be applied under a high vacuum to the light-emitting surface, wherein the matrix material and the converter material are produced on the light-emitting surface on deposition. The matrix material has the following structural formula

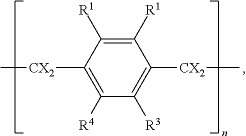

wherein R¹, R², R³, R⁴ and X may be mutually independently selected from the group comprising F, Cl and H, and

wherein n≧2. This example may be combined mutatis mutandis with all the abovestated examples.

“Vaporizable under high vacuum” may mean, for example, that the matrix material or the first precursor and the converter material or the second precursor may be applied by vaporization under high vacuum to a surface provided to emit radiation.

The converter material may be embedded in the matrix material such that the majority of the individual molecules of the converter material are mutually spaced by >3 nm and <150 nm relative to the longest longitudinal molecular axis of the converter material molecules. A spacing of >3 nm and <150 nm relative to the longest longitudinal molecular axis of the converter material molecules in particular has the advantage that the individual converter material molecules do not quench fluorescence. Such a minimum spacing may be produced by “co-vaporizing” converter material with a low concentration. “Co-vaporizing” means that the vaporization of converter material proceeds at the same time as that of the matrix material. By co-vaporizing matrix material and converter material, the converter material may be embedded in the matrix material and thus shield the individual converter material molecules from one another, such that fluorescence quenching (“concentration quenching”) is avoided. On the other hand, sufficient converter materials remain in the conversion layer for a high degree of concentration to be achieved together with high luminous efficiency of the light-emitting device.

The light-emitting device may take the form of or may be formed as an organic light-emitting diode (OLED) or light-emitting diode (LED).

The matrix material or the first precursor and the converter material or the second precursor may be selected such that they may be applied by vapor deposition in the same installation together with radiation-generating layers.

The conversion layer may be flat. The conversion layer may be applied flat to a radiation-emitting surface of a conversion element. The converter material or the second precursor and the matrix material or the first precursor may be sublimated under high vacuum and may therefore be applied under a high vacuum in the same vapor-deposition installation with which the radiation-generating layers of the device may also be applied.

The converter material may function in the conversion layer as a fluorescence converter. In particular, the converter material converts the primary electromagnetic radiation emitted by a radiation source into secondary electromagnetic radiation of a different wavelength. To this end, the converter material may be present in different concentrations in the matrix material. In particular, the converter material constitutes 0.001 wt. % to 10 wt. %, for example, 0.1 to 1 wt. %, of the matrix material. A plurality of converter materials may also be used in the conversion layer. The absorption band of at least one converter material should overlap at least in part with the wavelength range of the emitted radiation. The converter materials may be provided for identical or different emission wavelengths. Production takes place, for example, by simultaneous vaporization (co-vaporization) from a plurality of material sources. Thus, white emitting devices may be produced, in particular warm-white emitting devices.

In addition to the light-emitting device, a method of producing a light-emitting device is also provided. The same explanations and definitions apply to the method of producing a light-emitting device as were stated above for the light-emitting device and vice versa.

The method may comprise the following method steps:
A) providing a surface provided for radiation emission, and
B) vapor deposition of a conversion layer under high vacuum onto the surface provided for radiation emission, wherein the conversion layer comprises a matrix material and a converter material, which are applied simultaneously to the surface provided for radiation emission. The matrix material has the following structural formula:

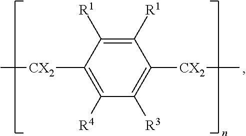

R¹, R², R³, R⁴ and X may be mutually independently selected from the group comprising F, Cl and H. The following applies: n≧2.

The matrix material may be produced from a first precursor in method step B), wherein the first precursor is [2,2]-paracyclophane or a derivative thereof.

The converter material may not be chemically modified in method step B). In other words, the converter material may have the same chemical composition prior to method step B) and after method step B).

Vapor deposition of the converter material may proceed in step B) together with the radiation-generating layer of the light-emitting device. Together may mean that vapor deposition proceeds in the same installation, but not at the same time. However, it may also mean that vapor deposition proceeds in the same installation at the same time. Matrix material and converter material may thus be simultaneously applied by vapor deposition. The radiation-generating layers, for example, of an organic light-emitting diode, may be applied by vapor deposition prior to the simultaneous vapor deposition of matrix material and converter material.

The conversion layer may be applied to an electrode layer from a material transparent to emitted radiation. In particular, the transparent material is indium-tin oxide. The transparent material may, for example, comprise a transparent conductive oxide or consist thereof. Transparent conductive oxides (“TCO” for short) are as a rule metal oxides such as, for example, zinc oxide, tin oxide, cadmium oxide, titanium oxide, indium oxide or indium tin oxide (ITO). In addition to binary metal-oxygen compounds such as, for example, ZnO, SnO₂ or In₂O₃, ternary metal-oxygen compounds such as, for example, Zn₂SnO₄, CdSnO₃, ZnSnO₃, MgIn₂O₄, GaInO₃, Zn₂In₂O₅ or In₄Sn₃O₁₂ or mixtures of different transparent conductive oxides also belong to the TCO group. The TCOs do not necessarily correspond to a stoichiometric composition and may moreover be p- or n-doped.

An organic light-emitting diode may be produced with the method. Alternatively, a light-emitting diode may be produced.

Hereinafter, the light-emitting device and a method of producing a light-emitting device is explained in greater detail below with reference to the drawings and on the basis of examples. Elements that are the same in the individual figures are indicated with the same reference numerals. The features shown on the drawings are, however, not to scale relative to one another. Rather, individual elements may be illustrated on an exaggeratedly large scale for better comprehension.

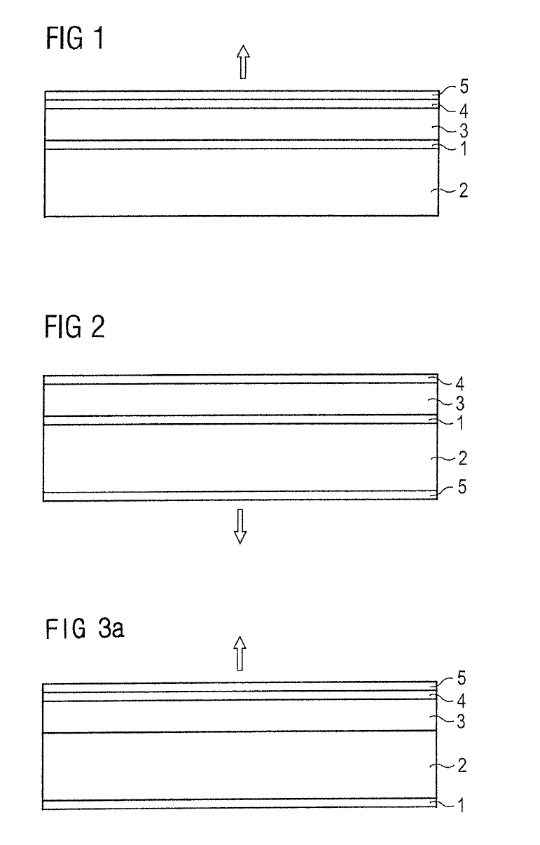

FIG. 1 is a schematic side view of a light-emitting device with reference to the example of an organic light-emitting diode (OLED). The OLED is a top emitter OLED. The OLED comprises a substrate 2. The substrate 2 may be glass. A first electrode 1 may be formed as a layer directly on the substrate 2. A multilayer structure 3 comprising radiation-generating layers may then be arranged to emit primary electromagnetic radiation. The multilayer structure 3 in particular comprises organic materials. The primary electromagnetic radiation in particular has a wavelength maximum of 430 nm to 700 nm. A second electrode 4 likewise in the form of a layer may be directly formed on the multilayer structure 3. The second electrode 4 may take the form of a cathode or anode, wherein the above-stated materials may be used. The second electrode 4 is in particular formed as an anode. The first electrode 1 may take the form of an anode or cathode. In particular, the first electrode 1 takes the form of or is formed as a cathode and may consist of a metal, preferably of a metal with high reflectivity. In particular, the second electrode 4 may be transparent. The conversion layer 5 is arranged directly on the second electrode 4. The conversion layer 5 converts the primary electromagnetic radiation into secondary electromagnetic radiation. The secondary electromagnetic radiation in particular has a wavelength maximum in the wavelength range of 450 to 800 nm. The OLED takes the form of a top emitter, thereby in particular emitting from the multilayer structure 3 towards the conversion element 5.

FIG. 2 is a schematic side view of a light-emitting device with reference to the example of an organic light-emitting diode. FIG. 2 differs from FIG. 1 in that the OLED is a “bottom emitter.” The conversion layer 5 is arranged directly under the substrate 2. In particular, the first electrode 1 is transparent in form. In addition, the substrate 2 is transparent in form. As a result, the primary electromagnetic radiation generated by the multilayer structure 3 may pass through the first electrode 1 and the substrate 2 into the conversion layer 5 and there be converted into secondary electromagnetic radiation and thus emitted from the device in the direction away from the second electrode 4.

The first and second electrodes 1, 4 may be transparent in form. In addition, the substrate 2 may be transparent. The OLED may be a top/bottom emitter (not shown).

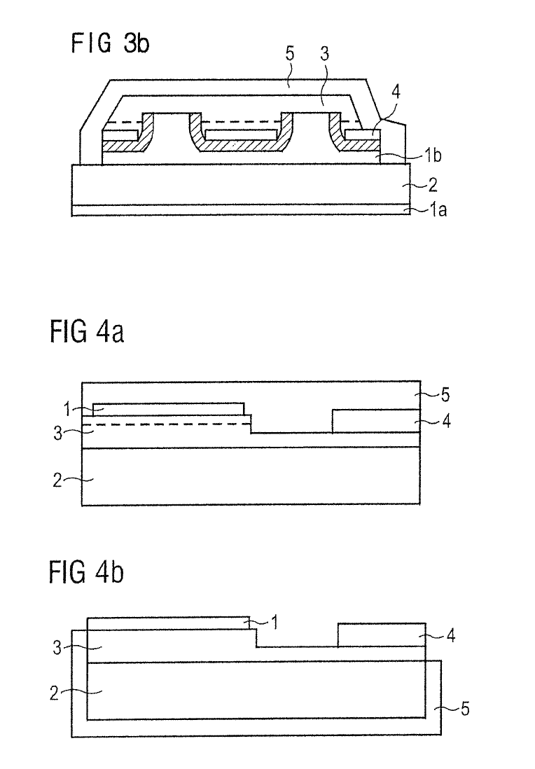

FIG. 3a is a schematic side view of a light-emitting device with reference to the example of a light-emitting diode. The light-emitting device comprises a semiconductor element. The semiconductor element comprises a first electrode 1 applied to a back of an electrically conductive substrate 2. The semiconductor element comprises a multilayer structure 3 located on the front of the substrate 2, which may comprise per se known layers of a light-emitting device and the details of which are not explained in greater detail. The multilayer structure 3 in particular comprises the active layers that generate radiation to generate the primary electromagnetic radiation. Boundary layers or cladding layers provided for current injection may additionally be provided. Bonding layers may also be present that connect the semiconductor layers mechanically, thermally and electrically with the substrate 2. On the side of the multilayer structure 3 remote from the substrate 2 there is located a second electrode 4, which in the example is applied over the entire surface and consists of a material transparent to the radiation to be emitted. On the top, the conversion layer 5 is applied to the second electrode 4 comprising a matrix material 11 and a converter material 10 preferably comprising the two materials that can be vaporized under high vacuum.

Radiation is emitted upwardly over the entire surface in the direction illustrated by the arrow.

FIG. 3b is a schematic side view of a light-emitting device with reference to the example of a light-emitting diode. The device comprises a first electrode 1 that may be composed of a solder contact layer 1a and a contact layer or current spreading layer 1b. A substrate 2 may be arranged between the solder contact layer 1a and the current spreading layer 1b. Furthermore, the device comprises a second electrode 4, a multilayer structure 3 and a conversion layer 5. The conversion layer 5 may be arranged flush on the substrate 2 and enclose the current spreading layer 1b, the second electrode 4 and the multilayer structure 3 and thus protect it from environmental influences.

FIG. 4a is a schematic side view of a light-emitting device with reference to the example of a light-emitting diode. The light-emitting device comprises a substrate 2, a multilayer structure 3, and a first and second electrode 1, 4 (sapphire chip). The first electrode 1 and the second electrode 4 are arranged on a multilayer structure 3. The two electrodes 1, 4 may be externally contacted. A conversion layer 5 may be applied to the two electrodes 1, 4.

FIG. 4b shows a schematic side view of a light-emitting device with reference to the example of a light-emitting diode. The light-emitting device comprises a substrate 2, a multilayer structure 3 and a first and second electrode 1, 4 (sapphire flip chip). The first electrode 1 and the second electrode 4 are arranged on a multilayer structure 3. The multilayer structure 3 is arranged on a substrate 2. A conversion layer 5 encloses the chip from 5 sides, wherein the sixth side comprises two electrodes for SMT mounting.

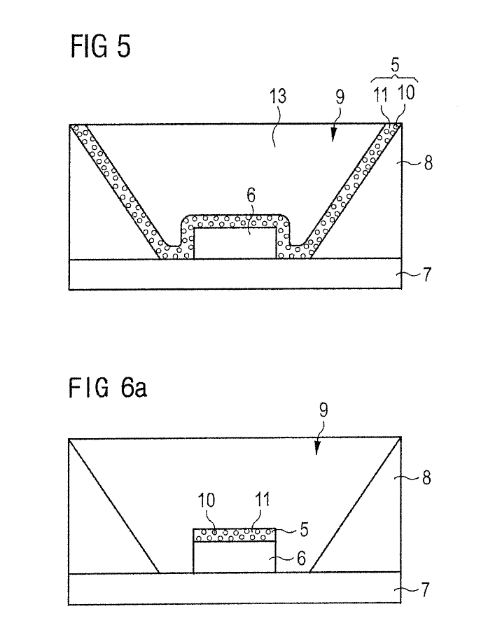

FIG. 5 is a schematic side view of a light-emitting device with reference to the example of a light-emitting diode. The light-emitting device comprises a carrier 7. The carrier 7 may extend laterally beyond the side faces of the semiconductor element 6 and the package 8 or terminate flush with the side faces of the package 8. The semiconductor element 6 is embedded in the package 8. The package 8 comprises a recess 9. The conversion layer 5 is formed in the recess 9. The conversion layer 5 covers, in particular completely, the side faces of the recess 9 and the side faces and surface of the semiconductor element 6. The conversion layer 5 comprises a conversion material 10 and a matrix material 11. The conversion layer 5 may be covered at least in the region of the semiconductor element 6 with a potting compound 13 that may completely fill the recess. The potting compound 13 may be clear. The potting compound 13 may comprise phosphorus particles.

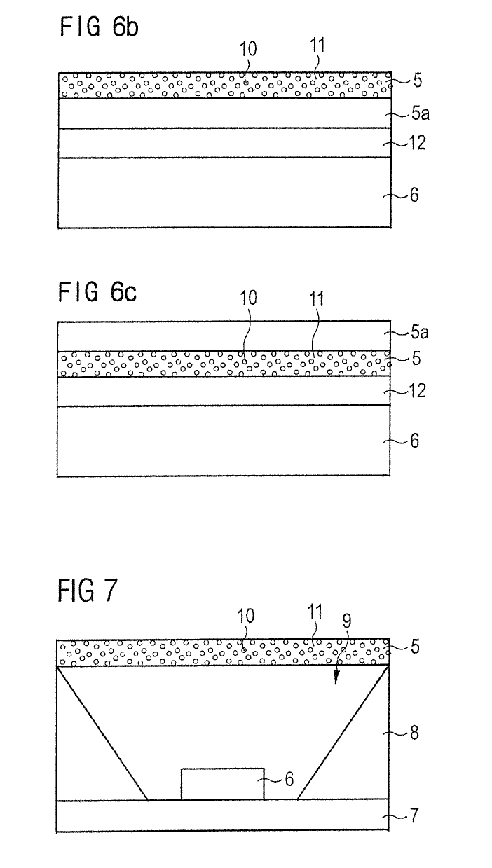

FIG. 6a is a schematic side view of a light-emitting device with reference to the example of a light-emitting diode. FIG. 6a differs from FIG. 5 in that the conversion layer 5 in FIG. 6a takes the form of or is formed as a film. The conversion element 5 takes the form in particular of a prefabricated film. Prefabricated means that the film is not directly deposited on the semiconductor element, but rather is applied to the semiconductor element 6 as a prefabricated film, for example, using a pick-and-place process. In other words, the conversion element 5 in the form of a film is produced spatially at a distance from the semiconductor element 6. The film may have a film thickness of ≦200 μm, for example, 30 to 100 μm.

The conversion element may comprise or consist of a transparent carrier film 5a, in addition to the conversion layer 5. The conversion element may be fastened to the semiconductor element 6 by a bonding layer 12. The bonding layer 12 may be an adhesive layer (FIGS. 6b and 6c). In FIG. 6b, the bonding layer 12 is arranged in direct contact with the transparent carrier film 5a and the transparent carrier film 5a is arranged in direct contact with the conversion layer 5. In FIG. 6c, the bonding layer 12 is arranged in direct contact with the conversion layer 5 and the conversion layer 5 is arranged in direct contact with the transparent carrier film 5a. After mounting the conversion element on the semiconductor element 6, the transparent carrier film 5a may be removed again (FIG. 6c).

FIG. 7 is a schematic side view of a light-emitting device with reference to the example of a light-emitting diode. FIG. 7 differs from FIG. 6a in that the conversion layer 5 takes the form of a film and is spatially at a distance from the semiconductor element 6. In particular, the conversion layer 5 is at a distance of 0.1 mm to 5 cm, preferably 0.5 mm to 5 mm, from the semiconductor element 6.

The devices and methods described herein are not restricted to the examples described. Rather, the disclosure encompasses any novel feature and any combination of features, including in particular any combination of features in the appended claims, even if the feature or combination is not itself explicitly indicated in the claims or examples.

Priority is claimed from DE 102014100837.5, the subject matter of which is hereby incorporated by reference

1-15. (canceled)

16. A light-emitting device comprising a conversion element comprising a light-emitting surface provided with a conversion layer, wherein
the conversion layer contains a matrix material and a converter material,
both the matrix material and the converter material are materials that can be vaporized under high vacuum,
the matrix material and the converter material are applied to the light-emitting surface by vaporization under a high vacuum, and
the matrix material has the structural formula 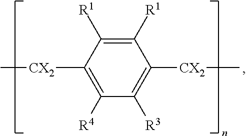
wherein R¹, R², R³, R⁴ and X may be mutually independently selected from the group comprising F, Cl and H, and n≧2.

17. The light-emitting device according to claim 16, wherein the converter material comprises or consists of an organic luminescent dye.

18. The light-emitting device according to claim 16, in which the conversion layer is arranged on an electrode layer or a semiconductor element of the light-emitting component, wherein the converter material is embedded in the matrix material such that a majority of individual molecules of the converter material are mutually spaced by greater than 3 nm and less than 150 nm relative to a longest longitudinal molecular axis of the converter material molecules.

19. The light-emitting device according to claim 17, wherein the matrix material protects the embedded converter material against environmental influences.

20. The light-emitting device according to claim 16, wherein the converter material is at least one selected from the group consisting of perylene and derivatives thereof, diindenoperylene and derivatives thereof, benzopyrene and derivatives thereof, coumarin and derivatives thereof, rhodamine and derivatives thereof, azo compounds, terrylene and derivatives thereof, quaterrylene and derivatives thereof, naphthalimide and derivatives thereof, cyanine or cyanines, phthalocyanine and derivatives thereof, fluorescein and derivatives thereof, fluorene and derivatives thereof, pyrene and derivatives thereof, pyranine and derivatives thereof, styryls, xanthene and derivatives thereof, oxazine and derivatives thereof, anthracene and derivatives thereof, naphthacene and derivatives thereof, anthraquinone and derivatives thereof and thiazine and derivatives thereof.

21. The light-emitting device according to claim 16,
wherein R¹, R², R³, R⁴ and X are in each case H, or
R¹ is Cl and R², R³, R⁴ and X are in each case H, or
R¹ and R³ are in each case Cl and R² and R⁴ and X are in each case H, or
R¹, R², R³ and R⁴ are in each case H and X is F.

22. The light-emitting device according to claim 16, formed as an organic light-emitting diode or light-emitting diode.

23. The light-emitting device according to claim 16, wherein the matrix material and the converter material are selected such that they may be applied by vapor deposition in a same installation together with radiation-generating layers.

24. A method of producing a light-emitting device comprising:
A) providing a surface provided for radiation emission, and
B) vapor depositing a conversion layer under high vacuum onto the surface provided for radiation emission, wherein the conversion layer comprises a matrix material and a converter material simultaneously applied to the surface provided for radiation emission, and the matrix material has structural formula 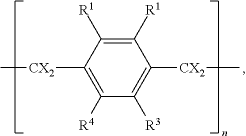
wherein R¹, R², R³, R⁴ and X may be mutually independently selected from the group comprising F, Cl and H, and n≧2.

25. The method according to claim 24, wherein the matrix material is produced from a first precursor in B), and the first precursor is [2,2]-paracyclophane or a derivative thereof.

26. The method according to claim 24, wherein the converter material is not chemically modified in B).

27. The method according to claim 24, in which vapor deposition proceeds in a same installation with which radiation-generating layers of the component are also applied by vapor deposition.

28. The method according to claim 24, in which the conversion layer is applied onto an electrode layer of a material transparent to emitted radiation.

29. The method according to claim 24, in which an organic light-emitting diode or light-emitting diode is produced.

30. The method according to claim 24, in which a light-emitting device is produced.
